(19) United States
(12) Patent Application Publication
(10) Pub. No.: US 2022/0254561 A1
(43) Pub. Date: Aug. 11, 2022

(54) TRANSFORMER AND PACKAGE MODULE

(71) Applicant: Hefei Silergy Semiconductor Technology Co., Ltd., Hefei city (CN)

(72) Inventors: Ke Dai, Hefei (CN); Jian Wei, Hefei (CN); Jiajia Yan, Hefei (CN)

(21) Appl. No.: 17/584,587

(22) Filed: Jan. 26, 2022

(30) Foreign Application Priority Data
Feb. 5, 2021 (CN) 202110161354.4

(51) Int. Cl. H01F 27/28; H01F 27/255; H05K 1/16; H05K 1/11; H01L 23/522

(52) U.S. Cl. CPC H01F 27/2804; H01F 27/255; H05K 1/165; H01F 2027/2809; H01L 23/5227; H01F 2027/2819; H05K 2201/086; H05K 1/111

(57) ABSTRACT

A transformer can include at least one magnetic core; a substrate having a planar winding inside; and where the substrate is stacked with at least one of the magnetic cores. A package module can include the transformer and a package backplane a package backplane that encapsulates a wafer; and where the package backplane is stacked with the transformer, and an upper surface of the package backplane is in contact with the magnetic core of the transformer.

### RELATED APPLICATIONS

This application claims the benefit of Chinese Patent Application No. 202110161354.4, filed on Feb. 5, 2021, which is incorporated herein by reference in its entirety.

### FIELD OF THE INVENTION

The present invention generally relates to the field of power electronics, and more particularly to transformers and associated package modules.

### BACKGROUND

The combination of magnetic components and packaging technology has always been an important issue in the development of power modules. Currently, the magnetic components (e.g., transformers) are soldered to the package backplane (see, e.g., FIG. 1) that encapsulates the chip inside through surface mount technology (SMT). However, as the switching frequency is gradually increased, the winding structure transformer may not be easily reduced as the switching frequency is improved due to limitations of the manufacturing process.

### BRIEF DESCRIPTION OF THE DRAWINGS

FIG. 1 is a structural diagram of an example package module.

FIG. 2 is a structural diagram of a first example transformer, in accordance with embodiments of the present invention.

FIGS. 3A and 3B are structural diagrams of a transformer substrate, in accordance with embodiments of the present invention.

FIG. 4 is a structural diagram of a second example transformer, in accordance with embodiments of the present invention.

FIG. 5 is a structural diagram of a first example package module, in accordance with embodiments of the present invention.

FIG. 6 is a structural diagram of a second example package module, in accordance with embodiments of the present invention.

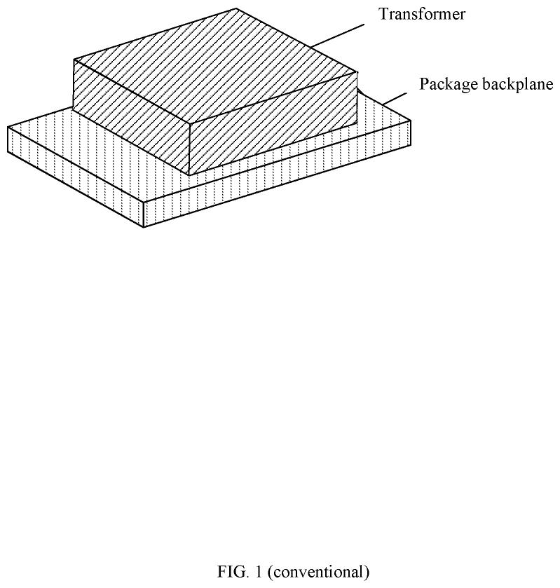

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

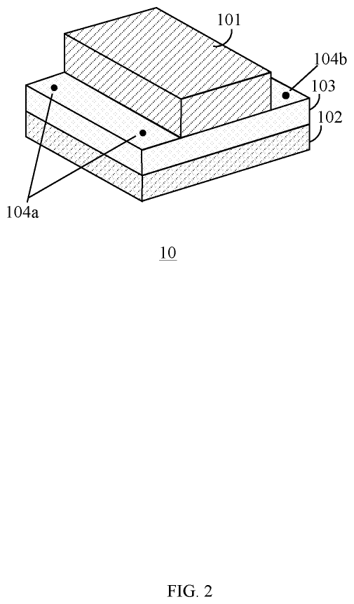

Referring now to FIG. 2, shown is a structural diagram of a first example transformer, in accordance with embodiments of the present invention. In particular embodiments, a transformer and a package module are provided to reduce the volume of the transformer and thereby reduce the volume of the package module that contains the transformer. In this particular example, the transformer 10 can include magnetic core 101, magnetic core 102, and substrate 103. Here, substrate 103 can include a planar winding, where the planar winding can include a primary winding and a secondary winding. Also, substrate 103 can be stacked with magnetic cores 101 and 102. For example, the side surface of substrate 103 can be exposed by magnetic cores 101 and 102.

Magnetic core 101 can be located on the upper surface of substrate 103, and magnetic core 102 can be located under substrate 103. For example, the horizontal area of magnetic core 101 can be smaller than the horizontal area of magnetic core 102. Also, the upper surface of substrate 103 can be opposite to the lower surface, and the inner planar windings in substrate 103 can be out of the first pad on the surface of substrate 103. For example, the first pad can include two primary side pads 104a and two sub-pads 104b, which can respectively connect to the lead terminals of the primary winding and the secondary winding. In this particular example, the first pad is located at the edge region of the substrate exposed by magnetic core 101.

In particular embodiments, the side surface of substrate 103 can be exposed by magnetic cores 101 and 102. In other example transformers, the side surface of the substrate can also be surrounded by the magnetic core. In still other example transformers, the first pad can also be located on the side of the substrate. In particular embodiments, transformer 10 can adjust the thickness of magnetic cores 101 and 102 in accordance with the switching frequency. For example, the higher the switching frequency, the thinner the thickness of the core. The shape of magnetic cores 101 and 102 can be rectangle, circle, polygon, etc., while in this particular example, magnetic cores 101 and 102 are rectangular. The materials of magnetic cores 101 and 102 can be ferrite or magnetic core material. In this particular example, magnetic cores 101 and 102 are made of ferrite.

In particular embodiments, substrate 103 may be disposed to coat the metal material on the printed-circuit board (PCB), in order to form a PCB winding. For example, the metal material is copper. Alternatively, the PCB winding can include at least four layers of windings. For example, substrate 103 can include two PCBs: a first PCB and a second PCB. The primary winding can be formed on the first PCB, and the secondary winding may be formed on the second PCB. Also, each PCB can be coated with metal material on its upper and lower surfaces to form two layers of windings through a redistribution layer (RDL) process. In other example transformers, the number of PCB and the number of windings formed on the PCB may be selected in accordance with specific transformer requirements or structural requirements.

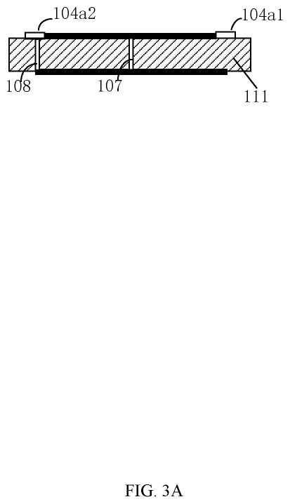

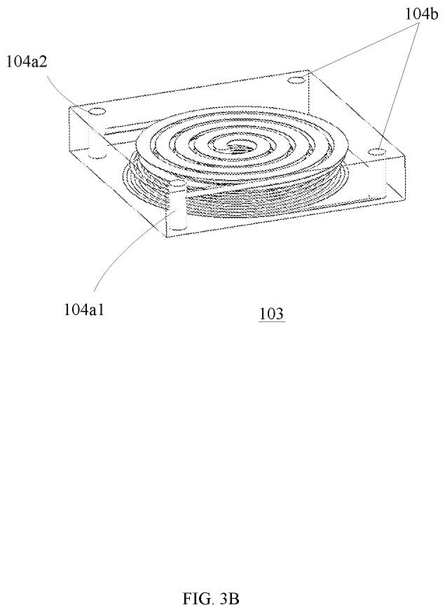

Referring now to FIGS. 3A and 3B, shown are structural diagrams of a transformer substrate, in accordance with embodiments of the present invention. FIG. 3A shows an example structural diagram of one of the PCB windings. Here, the upper and lower surfaces of PCB 111 can respectively be covered with metal to form two layers of windings. For example, the windings can be formed on the surface of the PCB through an RDL process. The two-layer windings can connect through via 107 in the PCB, and the PCB windings can be drawn out through two pads on the upper surface of the PCB. The two pads can include pad 104al and pad 104a2. Pad 104al can connect to the winding on the upper surface of PCB 111, and pad 104a2 can connect to the winding on the lower surface of PCB 111 through via 108. The other PCB winding may be formed in a similar manner. An insulating medium (e.g., FR-4 material) can also filled between the two PCB windings. The two PCB windings can be electrically connected by forming conductive channels in the insulating medium. FIG. 3B shows a structural diagram of substrate 103. The first PCB and the second PCB can form a four-layer winding through the above mentioned manner. For example, the shape (e.g., spiral) of each layer of winding can be as shown in FIG. 3B.

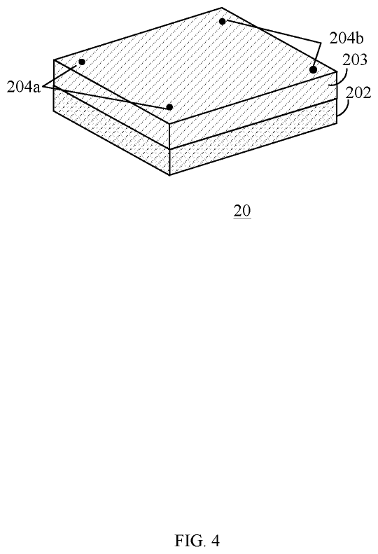

Referring now to FIG. 4, shown is a structural diagram of a second example transformer, in accordance with embodiments of the present invention. In this particular example, the transformer may have only one magnetic core. For example, transformer 20 can include magnetic core 202 and substrate 203. In particular embodiments, substrate 203 can include a planar winding, where the planar winding can include a primary winding and a secondary winding. Substrate 203 and magnetic core 202 can be stacked, and the side surface of substrate 203 may be exposed by magnetic core 202.

For example, magnetic core 202 can be located on the lower surface of substrate 203. Also, the upper surface of substrate 203 may be opposite to the lower surface, and the inner planar windings in substrate 203 can be drawn out through the first pads located on the upper surface of substrate 203. For example, the first pads can include two primary pads 204a that can connect to the primary winding lead terminals, and two secondary pads 204b that can connect to the secondary winding lead terminals. In particular embodiments, the first pad can be located on the edge region exposed by magnetic core 202.

In certain embodiments, transformer 20 can adjust the thickness of magnetic core 202 according to the switching frequency. For example, the higher the switching frequency, the thinner the thickness of the magnetic core. The shape of magnetic core 202 may be rectangular, circular, polygonal, etc., and magnetic core 202 is rectangular in this particular example. The material of magnetic core 202 can be a ferrite or magnetic powder core material, and is ferrite in this example. Here, substrate 203 can be substantially the same as the substrate in the first example discussed above. In this particular example, the magnetic core may not be stacked on the upper surface of the substrate, and the magnetic core may only be stacked on the lower surface of the substrate. In this way, the manufacturing process can be simplified.

In particular embodiments, the transformer can include at least one magnetic core and a substrate, which can include planar windings, where the substrate is stacked with at least one of the magnetic cores. Since the thickness of the package substrate is very thin, and the thickness of the magnetic core can also be thin, the thickness of the entire transformer can be thinner than conventional approaches, in order to reduce the volume of the transformer. Furthermore, the transformer can adjust the thickness of the magnetic core according to the switching frequency.

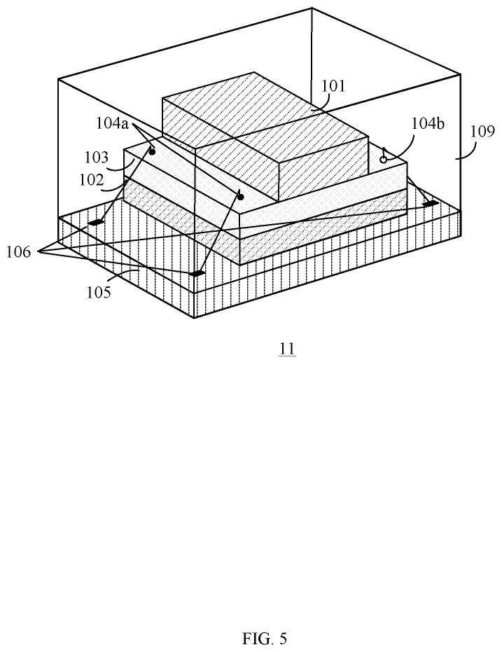

Referring now to FIG. 5, shown is a structural diagram of a first example package module, in accordance with embodiments of the present invention. In this particular example, package module 11 can include transformer 10 (see, e.g., FIG. 2) and package backplane 105, and the inside of package backplane 105 can encapsulate a wafer. For example, package backplane 105 can encapsulate the wafer by an insulating material. Package backplane 105 can be stacked with transformer 10, and the upper surface of package backplane 105 may be in contact with magnetic core 102 of transformer 10.

In addition, the upper surface of package floor 105 can include second pad 106. For example, the second pad can be located in the area exposed by the transformer, as the horizontal area of the package backplane is larger than the horizontal area of the transformer. In particular embodiments, the second pad of the package backplane can be coupled to the first pad connection of the transformer by wire bonding, in order to realize electrical connection between the package backplane and the transformer. In particular embodiments, the package backplane and the transformer can be encapsulated to form package body 109. Further, package body 109 can be filled with material powder, including magnetic materials, such as iron powder or ferrite powder, in order to increase the magnetic flux of the transformer and shield stray magnetic flux.

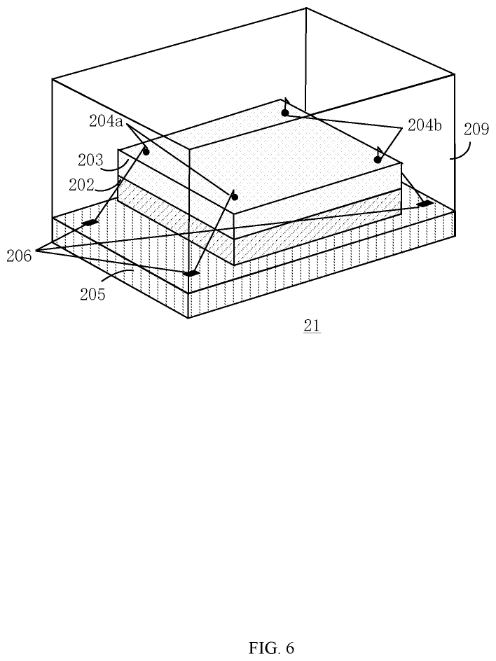

Referring now to FIG. 6, shown is a structural diagram of a second example package module, in accordance with embodiments of the present invention. In particular embodiments, package module 21 can include transformer 20 (see, e.g., FIG. 4) and package backplane 205. Also, and the package backplane 205 can encapsulate a wafer. For example, package floor 205 can encapsulate the wafer by insulating material. The package backplane 205 can be stacked with transformer 20, and the upper surface of package backplane 205 may be in contact with magnetic core 202 of transformer 20.

The upper surface of package backplane 205 can include second pad 206. For example, the second pad can be located in the area exposed by the transformer, as the horizontal area of the package backplane is larger than the horizontal area of the transformer. In particular embodiments, the second pad of the package backplane can be coupled to the first pad connection of the transformer by wire bonding, in order to realize electrical connection of the package backplane and the transformer. In particular embodiments, the packaged backplane and the transformer can be encapsulated to form package body 209. Package body 209 can be filled with magnetic material powder, such as iron powder or ferrite powder, in order to increase the magnetic flux of the transformer and shield stray magnetic flux.

In particular embodiments, a package module can include a transformer and an inner package backplane in which the package backplane is stacked with the transformer. Also, the upper surface of the package backplane is in contact with the magnetic core of the transformer. For example, the transformer can connect to the package backplane by wire bonding. In certain embodiments, since the transformer is thin and the package backplane and the transformer are stacked, the entire package module may remain thin, such that the volume of the package module can be reduced as compared to conventional approaches.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A transformer, comprising:
a) at least one magnetic core;
b) a substrate having a planar winding therein; and
c) wherein the substrate is stacked with at least one of the magnetic cores.

2. The transformer of claim 1, wherein the transformer adjusts the thickness of the magnetic core according to the switching frequency.

3. The transformer of claim 1, wherein the higher switching frequency, the thinner the thickness of the magnetic core.

4. The transformer of claim 1, wherein:
a) the transformer comprises a magnetic core located on a lower surface of the substrate;
b) the upper surface of the substrate comprising a first pad; and
c) the upper surface of the substrate is opposite to the lower surface of the substrate.

5. The transformer of claim 1, comprising two magnetic cores that are respectively located on an upper surface and a lower surface of the substrate, wherein the upper surface of the substrate is opposite to the lower surface of the substrate.

6. The transformer of claim 5, wherein a region of the substrate exposed by the magnetic core on its upper surface comprises a first pad.

7. The transformer of claim 1, wherein the substrate comprises a printed-circuit board (PCB) winding.

8. The transformer of claim 7, wherein the PCB winding is formed by cladding metal material on upper and lower surfaces thereof.

9. The transformer of claim 8, wherein the metal material comprises copper.

10. The transformer of claim 8, wherein the metal material is formed on the upper and lower surfaces of the PCB through a redistribution layer (RDL) process.

11. The transformer of claim 7, wherein the PCB winding comprises at least 4 winding layers.

12. The transformer of claim 7, wherein a planar winding comprises a primary winding and a secondary winding that is wired from the edge region of an upper surface of the substrate to connect to a first pad.

13. The transformer of claim 1, wherein a shape of the magnetic core is one of: rectangular, circular, and polygonal.

14. The transformer of claim 1, wherein the magnetic core material comprises ferrite or magnetic powder core material.

15. The transformer of claim 1, wherein a portion of an upper surface of the substrate is exposed by the magnetic core.

16. A package module, comprising the transformer of claim 1, and further comprising:
a) a package backplane that encapsulates a wafer; and
b) wherein the package backplane is stacked with the transformer, and an upper surface of the package backplane is in contact with the magnetic core of the transformer.

17. The package module of claim 16, wherein the upper surface of the package backplane is larger than a lower surface of the transformer.

18. The package module of claim 16, wherein the upper surface of the package backplane comprises a second pad.

19. The package module of claim 18, wherein the second pad of the package backplane is connected with a first pad of the transformer by wire bonding.

20. The package module of claim 16, wherein the package backplane and the transformer are encapsulated to form a first package body.
